(19) United States
(12) Patent Application Publication
(10) Pub. No.: US 2023/0266149 A1
(43) Pub. Date: Aug. 24, 2023

(54) ROTATION ANGLE DETECTOR, ROTATION ANGLE DETECTION METHOD, ROTATION ANGLE DETECTION PROGRAM, AND ROTATION ANGLE DETECTION SYSTEM

(71) Applicant: NIDEC COPAL CORPORATION, Tokyo (JP)

(72) Inventors: Kiyoyasu SAITO, Tokyo (JP); Tomohisa TOKUNAGA, Tokyo (JP)

(21) Appl. No.: 18/173,766

(22) Filed: Feb. 23, 2023

(30) Foreign Application Priority Data
Feb. 24, 2022 (JP) 2022-026725

(51) Int. Cl. G01D 5/14; G01R 33/09

(52) U.S. Cl. CPC G01D 5/145; G01R 33/093; G01R 33/091

(57) ABSTRACT

A rotation angle detector is smaller and less expensive and has higher detection accuracy. A rotation angle detector for detecting a rotation angle of a rotator including at least two pole pairs arranged in a ring includes an electrical angle calculator that calculates an electrical angle of the rotator, a pole pair number setter that sets a pole pair number for each of the at least two pole pairs in the rotator, an origin pole pair detector that detects, based on magnitudes of magnetic fluxes of the at least two pole pairs, an origin pole pair as an origin and sets an origin pole pair number to the origin pole pair, and an absolute mechanical-angle calculator that calculates an absolute mechanical angle of the rotator based on the electrical angle, the pole pair number, and the origin pole pair number.

### RELATED APPLICATIONS

The present application claims priority to Japanese Application Number 2022-026725, filed Feb. 24, 2022, the disclosure of which is hereby incorporated by reference herein in its entirety.

### BACKGROUND

### Technical Field

The present invention relates to a rotation angle detector, a rotation angle detection method, a rotation angle detection program, and a rotation angle detection system for detecting the rotation angle of a rotator.

### Description of the Background

For example, Patent Literature 1 describes a position detection sensor including a rotational shaft to which a detection target rotator is connected. A first rotor and a second rotor are fixed on the rotational shaft. The first rotor includes numerous pairs of different poles arranged alternately in the circumferential direction. The second rotor includes a single pair of different poles arranged in the circumferential direction. A housing for these rotors also accommodates a first sensor facing the first rotor from radially outside and a second sensor facing the second rotor from radially outside.

The first sensor outputs digital pulses. The second sensor generates an analog output. Sensor signals from the first sensor are interpolated by sensor signals from the second sensor to calculate an absolute mechanical angle.

### CITATION LIST

### Patent Literature

Patent Literature 1: Japanese Unexamined Patent Application Publication No. 10-311742

### BRIEF SUMMARY

However, the position detection sensor described in Patent Literature 1 includes the pair of rotors fixed coaxially with the rotational shaft and the pair of sensors accommodated in the housing for the respective rotors. The position detection sensor including many parts can be large and costly and also increase the manufacturing cost. The rotational shaft having a large moment of inertia is less controllable and may stop with less accuracy.

One or more aspects of the present invention are directed to a rotation angle detector, a rotation angle detection method, a rotation angle detection program, and a rotation angle detection system that are inexpensive, space-saving, and simple and have high detection accuracy.

A rotation angle detector according to one aspect of the present disclosure is a rotation angle detector for detecting a rotation angle of a rotator. The rotator includes at least two pole pairs arranged in a ring. The rotation angle detector includes an electrical angle calculator that calculates an electrical angle of the rotator, a pole pair number setter that sets a pole pair number for each of the at least two pole pairs in the rotator, an origin pole pair detector that detects, based on magnitudes of magnetic fluxes of the at least two pole pairs, an origin pole pair as an origin and sets an origin pole pair number to the origin pole pair, and an absolute mechanical-angle calculator that calculates an absolute mechanical angle of the rotator based on the electrical angle, the pole pair number, and the origin pole pair number.

The rotation angle detector, the rotation angle detection method, the rotation angle detection program, and the rotation angle detection system according to the above aspect of the present invention are inexpensive, space-saving, and simple and can have high detection accuracy.

### BRIEF DESCRIPTION OF DRAWINGS

FIG. 1 is a schematic partial cross-sectional view of a rotation angle detection system including a rotation angle detector.

FIG. 2 is a graph of the magnetic flux density (T) detected with a 12-pole ring magnet in comparison with the magnetic flux density (T) detected with a 2-pole ring magnet.

FIG. 3 is a schematic view of a ring magnet in a first embodiment together with a graph of the magnetic flux density detected with the ring magnet.

FIG. 4 is a diagram showing the relationship between the electrical angle, the mechanical angle, and the absolute mechanical angle in the first embodiment.

FIG. 5 is a block diagram of a rotation angle detector and a part of a rotation angle detection system according to the first embodiment.

FIG. 6A is a flowchart showing a part of an example operation performed by the rotation angle detector according to the first embodiment.

FIG. 6B is a flowchart showing a part of the example operation performed by the rotation angle detector according to the first embodiment.

FIG. 7 is a diagram of a magnetic detector in the first embodiment located at example positions.

FIG. 8 is a schematic view of a ring magnet in a first modification of the first embodiment together with a graph of the magnetic flux density detected with the ring magnet.

FIG. 9 is a schematic view of a ring magnet in a second modification of the first embodiment together with a graph of the magnetic flux density detected with the ring magnet.

FIG. 10 is a schematic view of ring magnets in third and fourth modifications of the first embodiment.

FIG. 11 is a schematic view of a ring magnet in a fifth modification of the first embodiment together with a graph of the magnetic flux density detected with the ring magnet.

FIG. 12 is a schematic view of a ring magnet in a sixth modification of the first embodiment together with a graph of the magnetic flux density detected with the ring magnet.

FIG. 13 is a schematic view of a ring magnet in a seventh modification of the first embodiment together with a graph of the magnetic flux density detected with the ring magnet.

FIG. 14 is a schematic view of ring magnets in eighth and ninth modifications of the first embodiment.

### DETAILED DESCRIPTION

One or more embodiments of the present invention will now be described with reference to the drawings. The embodiments are mere examples of the present disclosure. Any modifications that may occur to those skilled in the art without departing from the spirit of the invention fall within the scope of the present invention. For clarity, the drawings may be schematic and may not be drawn to scale relative to, for example, the actual width, thickness, and shape of each component. Such sizes are mere examples and do not limit the present invention.

In the specification and the drawings, like reference numerals denote like components that have been already described in any of the drawings. Such components may not be described in detail.

### First Embodiment

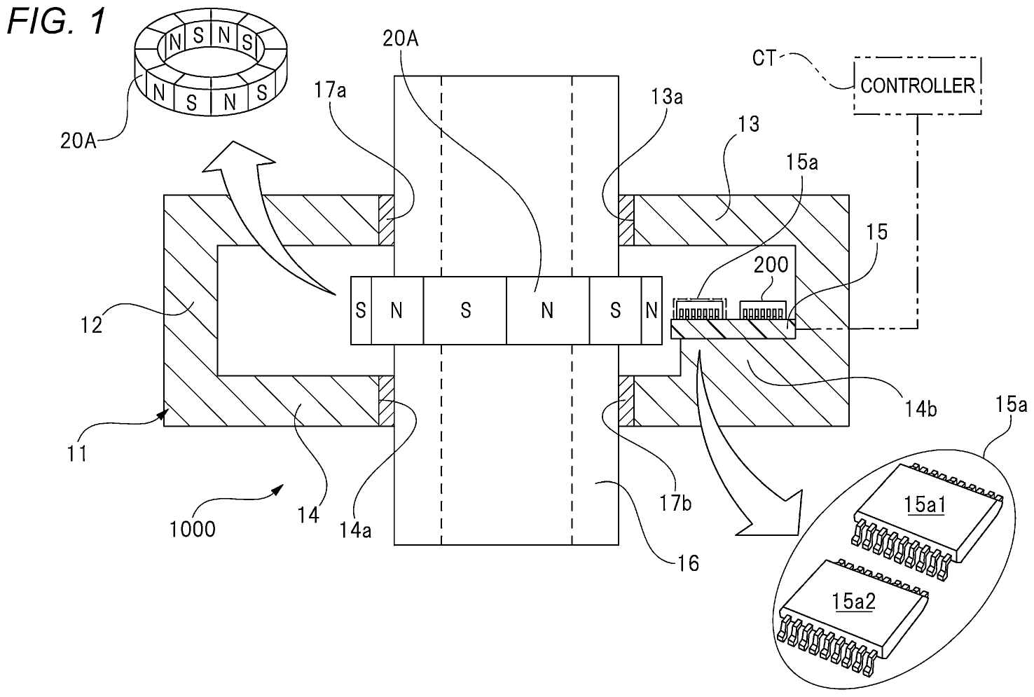

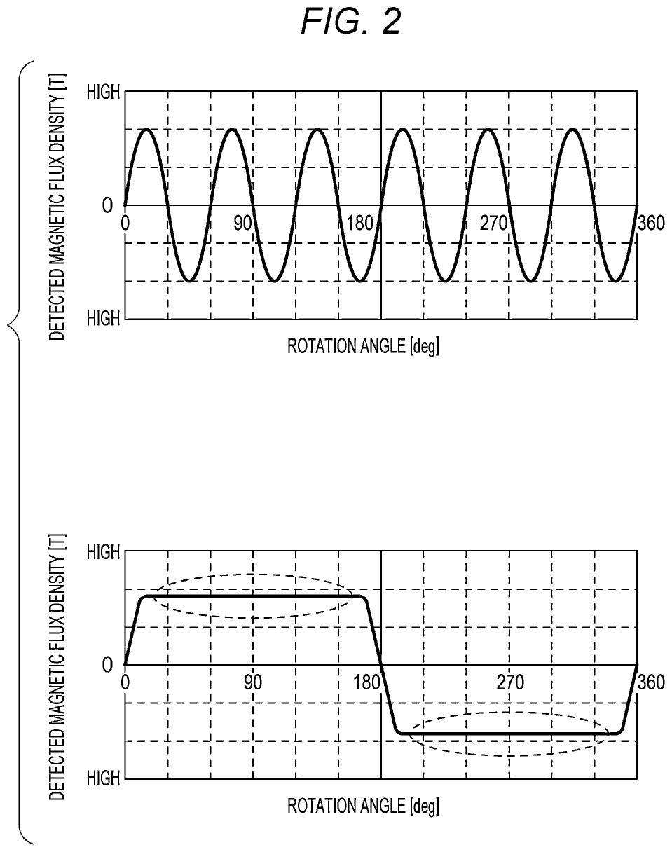

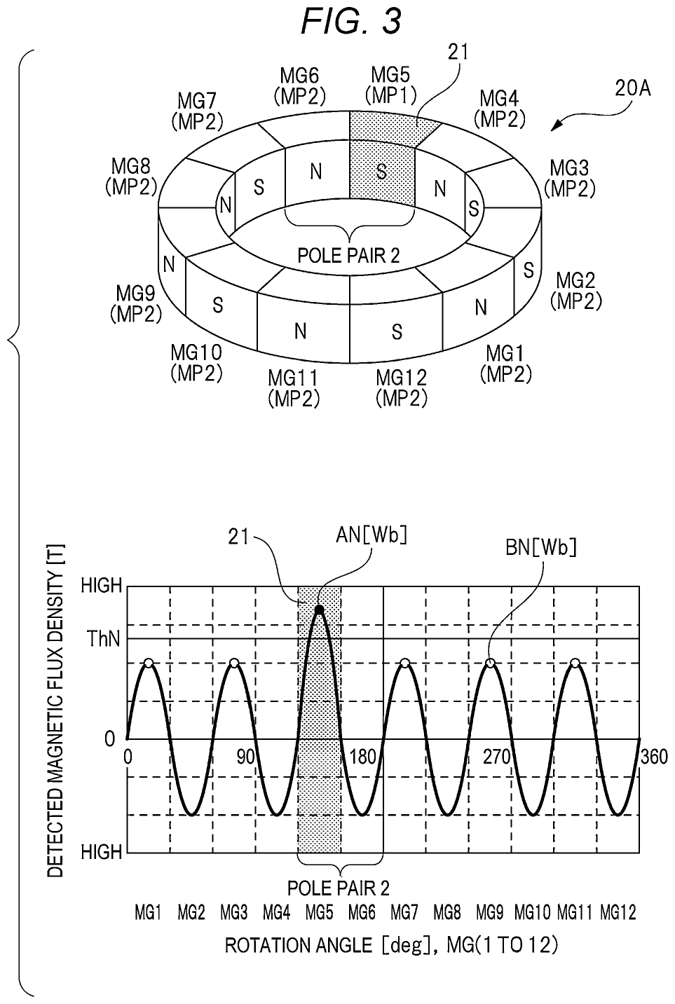

FIG. 1 is a schematic partial cross-sectional view of a rotation angle detection system including a rotation angle detector. FIG. 2 is a graph of the magnetic flux detected with a 12-pole ring magnet in comparison with the magnetic flux detected with a 2-pole ring magnet. FIG. 3 is a schematic view of a ring magnet in a first embodiment together with a graph of the magnetic flux detected with the ring magnet. Although the detected magnetic fluxes are each output as two electric signals, which are a sine wave electric signal and a cosine wave electric signal, the detected magnetic fluxes output as sine wave electric signals alone are described with reference to FIGS. 2 and 3.

A rotation angle detection system 1000 shown in FIG. 1 may be incorporated in, for example, a joint-drive servomotor (not shown) for an industrial robot. In this case, a controller CT that is electrically connected to a rotation angle detector 200 to control the industrial robot may control a joint-drive servomotor with high precision while accurately detecting the status of rotation of the joint-drive servomotor. The rotation angle detector 200 may have other uses. In other words, the rotation angle detector 200 according to the present embodiment may be used in many drive control circuits that are angle sensors or angle converters including a magnetic sensor and a multi-polar magnet and include a central processing unit (CPU), a field-programmable gate array (FPGA), or other devices for calculating an angle. The functions of the rotation angle detector 200 may be implemented by the controller CT. In this case, the functions of the rotation angle detector 200 are implemented by the CPU in the controller CT, or the CPU in the rotation angle detector 200 is included in the controller CT. In the embodiment below, the rotation angle detector 200 incorporated in a joint-drive servomotor (not shown) for an industrial robot will be described.

The rotation angle detection system 1000 may include a housing 11 that is a substantially annular disk with a hollow. The housing 11 includes a substantially cylindrical sidewall 12, a top plate 13 that closes the hollow at one axial end (upper end in the figure) of the sidewall 12, and a bottom plate 14 that closes the hollow at the other axial end (lower end in the figure) of the sidewall 12. Through-holes 13a and 14a extend through the center of each of the top plate 13 and the bottom plate 14 to allow a hollow shaft (rotator) 16 to be placed through the through-holes 13a and 14a.

The bottom plate 14 is integral with a substrate support 14b. The substrate support 14b is a protrusion inside the housing 11. A sensor board 15 including a magnetoresistive (MR) sensor 15a mounted on the sensor board 15 is fastened to the substrate support 14b with, for example, fastener screws (not shown). The MR sensor 15a functions as a magnetic detection unit. Thus, the MR sensor 15a is located inside the housing 11 and axially at the middle of the housing 11. The sensor board 15 is electrically connected to the controller CT with a connector (not shown). An electric signal converted from a detection signal (detected magnetic flux density in T) from the MR sensor 15a is output to the rotation angle detector 200.

The MR sensor 15a is specifically a magnetoresistive sensor that measures the magnetic flux (magnetic field) of a ring magnet 20A rotated by the hollow shaft 16. The MR sensor 15a includes a pair of MR sensors 15a1 and 15a2 functioning as magnetic detectors. The MR sensors 15a1 and 15a2 may be supplied in physically different integrated circuit (IC) packages or may be contained in a single IC package. In the present embodiment, the MR sensor 15a outputs a change in the magnetic flux of each pole pair as a sine wave electric signal of one cycle and a cosine wave electric signal of one cycle in response to rotation of the rotator. For example, the MR sensor 15a1 outputs a change in the magnetic flux of a single pole pair as a sine wave electric signal of one cycle in response to rotation of the rotator. The MR sensor 15a2 outputs a change in the magnetic flux of the single pole pair as a cosine wave electric signal of one cycle in response to rotation of the rotator. The cosine wave is shifted from the sine wave by 90 degrees in the electrical angle. The MR sensor to output a sine wave electric signal or a cosine wave electric signal may be determined by changing the positions of the MR sensors 15a1 and 15a2.

The rotation angle detection system 1000 includes the hollow shaft 16 that rotates integrally with a rotational shaft in the joint-drive servomotor. The hollow shaft 16 is placed through the through-holes 13a and 14a and is rotatably supported by the top plate 13 and the bottom plate 14 of the housing 11 with a pair of bearings 17a and 17b. Thus, the housing 11 supports the hollow shaft 16 in a manner rotatable freely.

The hollow shaft 16 is substantially cylindrical and has a radial internal space to accommodate electric wires (wiring) for driving, for example, another joint-drive servomotor. The bearings 17a and 17b are metal sliding bearings that are also referred to as plain metal bearings. Thus, the hollow shaft 16 can rotate smoothly relative to the housing 11.

The rotation angle detection system 1000 includes the ring magnet (magnet) 20A. The ring magnet 20A is located on the hollow shaft 16 radially outward and inside the housing 11. The ring magnet 20A is, for example, a magnet formed from a ferrite magnetic material.

The ring magnet 20A is fixed to the hollow shaft 16 with an adhesive (not shown) formed from, for example, an epoxy resin, and is rotated by rotation of the hollow shaft 16. In other words, the ring magnet 20A rotates together with the hollow shaft 16 inside the housing 11.

The ring magnet 20A, as well as the MR sensor 15a, is located axially at the middle of the housing 11. Thus, the MR sensor 15a is located radially outward from the ring magnet 20A at a predetermined clearance (air gap). The MR sensor 15a faces the ring magnet 20A. The MR sensor 15a can thus detect (measure) the magnetic fluxes of multiple magnetized sections (12 poles) included in the ring magnet 20A in response to rotation of the hollow shaft 16. A magnetic flux detection unit may be located on an extension of the radius of rotation of the multiple pole pairs on the rotator described above, or may be located on a line intersecting with the extension of the radius of rotation of the multiple pole pairs. In other words, the MR sensor 15a functioning as a magnetic flux detection unit may be located obliquely to the radial direction of the ring magnet 20A.

The waveform of a detection signal (detected magnetic flux) output from the MR sensor 15a changes in accordance with the number of magnetized sections (number of poles) in the ring magnet 20A. The number of magnetized sections (number of poles) for detecting the rotation angle using the sine wave detection signal output from the MR sensor 15a will now be described.

The upper graph in FIG. 2 shows the waveform of the detection signal with the ring magnet 20A including 12 poles. The lower graph in FIG. 2 shows the waveform of the detection signal with the ring magnet 20A including two poles. The horizontal axis indicates the rotation angle (deg) of the hollow shaft 16. The vertical axis indicates the magnetic flux density (T) detected by the MR sensor 15a. A part of the detected magnetic flux density waveform protruding upward from the boundary line 0 (reference) represents a magnetic flux density detected with an N-polar magnetized section. A part of the magnetic flux density waveform protruding downward represents a magnetic flux density detected with an S-polar magnetized section.

As shown in the upper graph in FIG. 2, with the ring magnet 20A including 12 poles, the magnetic flux density detected by the MR sensor 15a is plotted as a sine wave in the shape of arcs smoothly connecting in the horizontal axis direction (representing the rotation angle). Thus, using the magnetic flux density detected by the MR sensor 15a as a sine wave allows the magnetic flux density detected by the MR sensor 15a to constantly vary as the rotation angle of the hollow shaft 16 changes (between 0 and 360 degrees). The rotation angle detector 200 can thus accurately detect the rotation angle of the hollow shaft 16 based on the detection signal from the MR sensor 15a.

As shown in the lower graph in FIG. 2, with the ring magnet 20A including two poles, the magnetic flux density detected by the MR sensor 15a is plotted as a square wave. In other words, the waveform includes parts (enclosed by dashed ovals) extending straight in the horizontal axis direction (representing the rotation angle). The detected magnetic flux density thus remains constant while the rotation angle of the hollow shaft 16 is in ranges from about 30 to 150 degrees and from about 210 to 330 degrees, or in other words, in ranges covering a major range of rotation angles of the hollow shaft 16. Thus, the rotation angle detector 200 cannot detect the rotation angle of the hollow shaft 16 accurately.

To accurately detect the rotation angle of the hollow shaft 16, the ring magnet 20A may include as many magnetized sections (poles) as appropriate (multi-polar ring magnet). In the present embodiment, the ring magnet 20A includes 12 poles in an appropriate structure.

However, as shown in the upper graph in FIG. 2, the peak values of the detected magnetic flux density on the N pole and the peak values on the S pole are all the same magnitude on both the N pole and S pole. Using such a detection signal (detected magnetic flux density), the rotation angle detector 200 detects multiple peak values with no difference and cannot detect the origin of the hollow shaft 16.

In the present embodiment, one section (origin-indicator magnetized section) of the total of 12 magnetized sections (12 poles) generates a magnetic flux that serves as an index (mark). The rotation angle detector 200 can thus detect the origin of the hollow shaft 16 as well.

### Details of Ring Magnet

The structure of the ring magnet 20A in the present embodiment will now be described in detail with reference to the drawings.

As shown in FIGS. 1 and 3, the ring magnet 20A is annular and has a radially inner surface fixed to the hollow shaft 16 and a radially outer surface facing the MR sensor 15a. The ring magnet 20A includes a total of 12 magnetized sections MG1 to MG12. More specifically, the odd-numbered magnetized sections (MG1, 3, 5, 7, 9, and 11) have N-polar radially outer ends, whereas the even-numbered magnetized sections (MG2, 4, 6, 8, 10, and 12) have S-polar radially outer ends.

In other words, the ring magnet 20A is a ring with the magnetized sections MG1 to MG12 having different poles (N pole and S pole) and being alternately arranged in the direction of rotation of the hollow shaft 16. In the present embodiment, the ring magnet 20A includes 12 circumferential sections of an annular magnetic material magnetized alternately to have N poles and S poles. In some embodiments, substantially tiled magnets (not shown) may be magnetized and attached around the hollow shaft 16. A pair of magnetized sections having different poles is referred to as a pole pair in the present embodiment. A pole pair number is set for each pole pair by the rotation angle detector 200. In FIG. 3, for example, the magnetized sections MG5 and MG6 are a pole pair, for which the pole pair number 2 is set by the rotation angle detector 200. The pole pair number will be described in detail later.

In the present embodiment, as shown in FIG. 3, the magnetized section MG5 (shaded area in the figure), of the 12 magnetized sections MG1 to MG12, serves as an origin-indicator magnetized section 21 (strongly magnetized section). In other words, the multiple magnetized sections MG1 to MG12 include the origin-indicator magnetized section 21 (magnetized section MG5), which generates a (high) magnetic flux density indicating that the hollow shaft 16 has completed one rotation. More specifically, the origin-indicator magnetized section 21 has a magnetic force different from the magnetic force from each of the other magnetized sections MG1 to MG4 and MG6 to MG12, which is larger than the magnetic forces from the other magnetized sections MG1 to MG4 and MG6 to MG12. The magnetized sections MG1 to MG12, including the origin-indicator magnetized section 21 (magnetized section MG5), each have the same volume.

In this structure, the MR sensor 15a facing the ring magnet 20A detects a sinusoidal magnetic flux as shown in the lower graph in FIG. 3. More specifically, the MR sensor 15a detects a higher magnetic flux density when facing the origin-indicator magnetized section 21 (magnetized section MG5) than when facing any one of the other N-polar magnetized sections MG1, MG3, MG7, MG9, and MG11, as shown in the shaded area in the graph. In the figure, the magnetic flux density level AN (T) detected at the black-dotted peak (marked with a black dot at one point) is about 1.5 times higher than the magnetic flux density level BN (T) detected at the other white-dotted peaks (marked with white dots at five points) (AN≈1.5×BN). Specifically, when the magnetic flux density level AN (T) at the point marked with a black dot represents a ripple of 100%, the magnetic flux density level BN (T) detected at the points marked with white dots represents a ripple of about 90% (a ripple difference is about 10%).

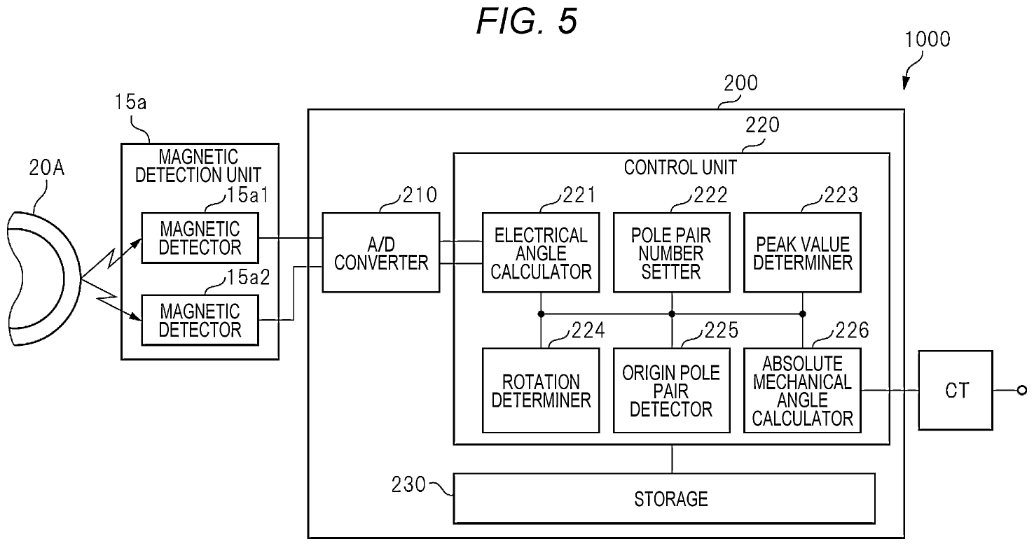

Thus, the rotation angle detector 200 detecting the single outstanding peak point (marked with a black dot) can detect the origin or reference point of rotation of the hollow shaft 16. More specifically, the rotation angle detector 200 compares the detected magnetic flux density level AN (T) as the major peak value (marked with a black dot) and the detected magnetic flux density level BN (T) as the minor peak value (marked with a white dot) with a comparison threshold ThN (T) stored in a storage 230 (FIG. 5) in the rotation angle detector 200 (AN>ThN>BN). The rotation angle detector 200 thus detects the single major N-polar peak value (marked with a black dot) between 0 and 360 degrees and determines that the pole pair including the N pole corresponding to the detected peak is an origin pole pair indicating the origin of the hollow shaft 16.

The single major peak value between 0 and 360 degrees may be an S-polar peak instead of an N-polar peak. The rotation angle detector 200 can detect an origin pole pair indicating the origin of the hollow shaft 16 as well. The magnetized sections MG1 to MG12 are thermally demagnetized or magnetized, or have the magnetic forces decreasing or increasing as the temperature changes. The magnetic forces may decrease due to aging degradation. The rotation angle detector 200 can change and adjust the comparison threshold ThN based on environmental changes including temperature changes and secular changes including aging degradation. The rotation angle detector 200 detects an origin pole pair by comparing the detected magnetic flux density level AN (T). The MR sensor 15a as a magnetic detection unit may thus be located on an extension of the radius of rotation of the multiple pole pairs on the rotator as shown in FIG. 1, or may be located on a line intersecting with the extension of the radius of rotation of the multiple pole pairs.

### Example Method of Magnetization

To magnetize the ring magnet 20A as described above, for example, a magnetizer (not shown) is used for generating a magnetic field in the radial direction. More specifically, the magnetizer includes a total of 12 magnetic force generators corresponding to the magnetized sections MG1 to MG12 (12 poles) in the ring magnet 20A. The coil in the magnetic force generator for the magnetized section MG5 has a larger number of turns than that of the coils in the magnetic force generators for the other magnetized sections MG1 to MG4 and MG6 to MG12.

In other words, a magnetic force MP1 generated by the magnetic force generator for the magnetized section MG5 is larger than magnetic forces MP2 generated by the other magnetic force generators (MP1>MP2). The ring magnet 20A as shown in FIG. 3 may thus be formed.

In some embodiments, for the magnetic force generator for the magnetized section MG5 to have a larger magnetic force, the coil in the magnetic force generator for the magnetized section MG5 may have a larger wire diameter than the magnetic force generators for the other magnetized sections, whereas the coils in all magnetic force generators have the same number of turns.

As described in detail above, the rotation angle detector 200 according to the first embodiment includes the ring magnet 20A that rotates together with the hollow shaft 16 and includes the magnetized sections MG1 to MG12 having different poles and being alternately arranged in the direction of rotation of the hollow shaft 16, and the MR sensor 15a that detects the magnetic fluxes of the magnetized sections MG1 to MG12. The magnetized sections MG1 to MG12 include the origin-indicator magnetized section 21 that allows detection of the origin or reference point of rotation of the hollow shaft 16.

The controller CT electrically connected to the rotation angle detector 200 can thus detect both the rotation angle and the origin of the hollow shaft 16 using the single ring magnet 20A and the single MR sensor 15a. The rotation angle detector 200 is thus smaller and less expensive and has higher detection accuracy.

In addition, the magnetic force MP1 from the origin-indicator magnetized section 21 (magnetized section MG5) is larger than the magnetic forces MP2 from the other magnetized sections MG1 to MG4 and MG6 to MG12 included in the multiple magnetized sections MG1 to MG12 (MP1>MP2).

Thus, the ring magnet 20A can be magnetized using a known magnetizer with minor modifications. This structure reduces an increase in the manufacturing cost.

### Calculation of Electrical Angle and (Absolute) Mechanical Angle

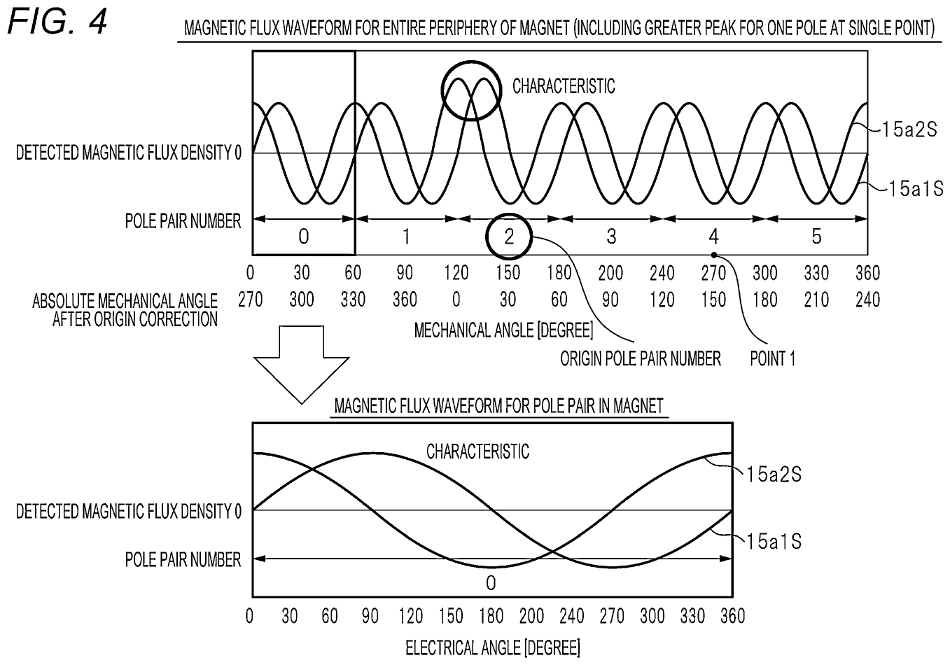

Methods for calculating the electrical angle and the (absolute) mechanical angle of the ring magnet 20A will now be described with reference to FIG. 4. The mechanical angle indicates the physical rotation angle of the ring magnet 20A. The mechanical angle ranges from 0 to 360 degrees for one rotation of the ring magnet 20A. The electrical angle indicates, for a pole pair of adjacent magnetized sections having different poles, an angle of 0 to 360 degrees in the range of rotation angles of the hollow shaft 16 facing the pole pair. For example, the structure according to the present embodiment includes six pole pairs. In this structure, the pole pair number 0 corresponds to the mechanical angle ranging from 0 to 60 degrees as shown in the upper graph in FIG. 4, and corresponds to the electrical angle ranging from 0 to 360 degrees as shown in the lower graph in FIG. 4. The pole pair numbers are assigned to the pole pairs in the ring magnet 20A facing the MR sensors 15al and 15a2. The method for calculating the electrical angle will be first described below.

As described with reference to FIG. 3, the MR sensor 15a1 in the MR sensor 15a facing the ring magnet 20A outputs a sine wave detection signal (detected magnetic flux density in T) 15a1S as shown in the lower graph in FIG. 4. As shown in the lower graph in FIG. 4, the MR sensor 15a2 in the MR sensor 15a outputs a cosine wave detection signal (detected magnetic flux density in T) 15a2S with its phase shifted by 90 degrees from the sine wave detection signal (detected magnetic flux density in T) 15a1S from the MR sensor 15a1. The MR sensor 15a2 may be at any position that allows the electrical angles of detection signals (detected magnetic flux densities in T) with the same magnitude output from a pair of magnetic poles to differ from each other by 90 degrees. The MR sensor 15a2 is at any position that satisfies the above condition. As shown in FIG. 1, for example, the MR sensor 15a2 may be adjacent to the MR sensor 15a1 to allow the electrical angles to differ from each other by 90 degrees.

As shown in the upper graph in FIG. 4, the mechanical angle ranges from 0 to 360 degrees for one rotation of the ring magnet 20A. As described above, the electrical angle shown in the lower graph in FIG. 4 ranges from 0 to 360 degrees within a pair of magnetic poles (pole pair). The method for calculating the electrical angle is known and will not be described in detail. The electrical angle can be calculated using Formula 1 below, where cos is the cosine wave detection signal (detected magnetic flux density in T) 15a2S, and sin is the sine wave detection signal (detected magnetic flux density in T) 15a1S.

θ_{EI} (electrical angle)=Arctan 2(cos,sin) (1)

The method for calculating the mechanical angle is also known and will not be described in detail. The mechanical angle can be calculated using Formula 2 below.

θ_{Mec} (mechanical angle)=(θ_{EI} (electrical angle)/number of pole pairs (6))+((360 degrees×pole pair number)/number of pole pairs (6)) (2)

(The pole pair number is assigned to a pole pair in the ring magnet 20A facing the MR sensors 15a1 and 15a2. The structure in the present embodiment includes six pole pairs, and the numbers 0 to 5 are set as example pole pair numbers.)

The number of pole pairs (6) indicates the number of pole pairs being six in the present embodiment.

However, the mechanical angle expressed by Formula 2 does not reflect the pole pair number serving as the origin, and is thus a relative mechanical angle based on the pole pair detected first by the MR sensors 15a1 and 15a2. For example, the pole pair number as a reference (e.g., 0) is assigned to a pole pair facing the MR sensors 15a1 and 15a2 when the rotation angle detector 200 and the MR sensors 15a1 and 15a2 are powered on. Thus, the absolute positional relationship cannot be determined. To calculate the absolute mechanical angle, an origin-indicator magnetized section is to be detected from the multiple magnetized sections MG1 to MG12, and a pole pair that serves as the origin is to be determined, as described above. As shown in the upper graph in FIG. 4, for example, when a characteristic magnetized section is detected in the pole pair 2, and the electrical angle at point 1 is 180 degrees, the absolute mechanical angle at point 1 can be calculated using Formula 3.

### Conversion Formula for Absolute Mechanical Angle

θ_{MecAbs} (absolute mechanical angle)=(θ_{EI} (electrical angle)/number of pole pairs (6))+((360 degrees×(pole pair number−origin pole pair number))/number of pole pairs (6) (3)

When the number obtained by subtracting the origin pole pair number from the pole pair number is negative, the actual number of pole pairs is added ((pole pair number−origin pole pair number)+number of pole pairs) to allow the number to fall within the range from zero to (number of pole pairs−1).

For example, the pole pair number is 4 and the electrical angle is 180 degrees at point 1 in the upper graph in FIG. 4, and the origin pole pair number is 2. The absolute mechanical angle is thus calculated using Formula 4.

θ_{MecAbs} (absolute mechanical angle)=180 degrees/6+(360×(4−2))/6=30 degrees+120 degrees=150 degrees (4)

The rotation angle detector that can perform the above calculations will be described in detail below.

### Example Structure of Rotation Angle Detector

FIG. 5 is a block diagram of an example part of the rotation angle detection system including the rotation angle detector according to the present embodiment.

The rotation angle detection system 1000 includes the ring magnet 20A that rotates together with the rotator, a magnetic detection unit 15a, and the rotation angle detector 200.

The ring magnet 20A described above will not be described in detail. A pole pair that serves as the origin is magnetized with various methods as in modifications described later.

The magnetic detection unit 15a includes the MR sensors 15a1 and 15a2 that function as magnetic detectors. The MR sensor 15a1 detects the magnetic flux density of the ring magnet 20A and outputs, for a change in the magnetic flux density of a pair of magnetic poles in the ring magnet 20A, a sine wave of one cycle as an output signal. The MR sensor 15a2 detects the magnetic flux density of the ring magnet 20A and outputs, for a change in the magnetic flux density of a pair of magnetic poles in the ring magnet 20A, a cosine wave of one cycle as an output signal. The MR sensor 15a2 may output a sine wave as an output signal. The MR sensor 15a1 may output a cosine wave as an output signal.

The MR sensors 15a1 and 15a2 are attached, with respect to the direction of rotation of the ring magnet 20A, to positions that allow the electrical angles to have their phases shifted by 90 degrees within a single pole pair.

The rotation angle detector 200 includes an analog-to-digital (A/D) converter 210, a control unit 220, and the storage 230.

The A/D converter 210 converts analog sine and cosine magnetic flux detection signals output from the magnetic detection unit 15a to digital signals that can be processed in the control unit 220 and the storage 230. The A/D converter 210 may be incorporated in the magnetic detection unit 15a. The A/D converter 210 may be a separate module.

The control unit 220 may be a hardware device including, for example, a semiconductor circuit and a microcomputer (not shown) that perform processes associated with the functions of the components in the block diagram, which will be described later. The control unit 220 may be included in a general-purpose server or a virtual server built by a cloud computing service. The control unit 220 may be a CPU (not shown). The control unit 220 may be implemented by executing middleware such as an operating system (OS) loaded from a recording device including a hard disk drive (HDD) into a memory or software running on such middleware. The processes associated with the functions, which will be described later, may be performed using the middleware or the software described above.

The control unit 220 may also be implemented by a combination of such hardware and software as appropriate. The control unit 220 may not be entirely implemented in a single casing. Some of the functions may be implemented in another casing, and these casings may be interconnected with, for example, a communication cable. In other words, the implementation of the control unit 220 is not limited and may be flexibly modified as appropriate based on, for example, the system environment.

The control unit 220 may be implemented in combination with other devices in the system. For example, the control unit 220 may be implemented after being added to other hardware or software in the system. The A/D converter 210 may be incorporated in the control unit 220. The control unit 220 may be incorporated in the controller CT.

The control unit 220 includes an electrical angle calculator 221, a pole pair number setter 222, a peak value determiner 223, a rotation determiner 224, an origin pole pair detector 225, and an absolute mechanical-angle calculator 226.

The electrical angle calculator 221 calculates the electrical angle within a single pole pair. More specifically, the electrical angle calculator 221 calculates and outputs, using Formula 1, the electrical angle based on the sine wave magnetic flux density detection signal and the cosine wave magnetic flux density detection signal output from the A/D converter 210. The sine wave magnetic flux density detection signal and the cosine wave magnetic flux density detection signal may be distinguished from each other based on identification information about an input port of the electrical angle calculator 221 that receives the sine wave magnetic flux density detection signal and identification information about an input port that receives the cosine wave magnetic flux density detection signal.

The pole pair number setter 222 performs initialization in response to the rotation angle detector 200 being powered on and sets a pole pair number to 0 or to a predetermined integer. The pole pair number setter 222 also increments or decrements the pole pair number based on electrical angle information indicating the electrical angle output from the electrical angle calculator 221. For example, in response to the electrical angle indicated by the electrical angle information changing from 360 to 0 degrees, the pole pair number setter 222 increments the pole pair number by one. In response to the electrical angle indicated by the electrical angle information changing from 0 to 360 degrees, the pole pair number setter 222 decrements the pole pair number by one. When the resulting pole pair number exceeds the maximum pole pair number, the pole pair number setter 222 may set the pole pair number to 0. When the resulting pole pair number is a negative number, the pole pair number setter 222 may set the pole pair number to the maximum pole pair number.

The peak value determiner 223 determines, within a single pole pair, a peak value of the sine wave magnetic flux density detection signal and the cosine wave magnetic flux density detection signal output from the A/D converter 210, and stores the peak value into the storage 230. The peak value indicates the maximum value or the minimum value. The peak value determined by the peak value determiner 223 indicates the maximum value or the minimum value depending on the magnetization method used to magnetize the characteristic magnetized section. In the present embodiment, for example, the characteristic magnetized section is magnetized to have the maximum value. The peak value determiner 223 thus detects the maximum value within each pole pair and stores the detected maximum value into the storage 230. For the maximum value, one or both of the maximum values of the sine wave magnetic flux density detection signal and the cosine wave magnetic flux density detection signal may be detected and stored into the storage 230 as the maximum value. The maximum value determined by the peak value determiner 223 is associated with the corresponding pole pair number set by the pole pair number setter 222 and stored into the storage 230. In other words, the maximum value corresponding to each pole pair number is stored into the storage 230.

The rotation determiner 224 determines whether the ring magnet 20A has completed one rotation. For example, the rotation determiner 224 determines that the ring magnet 20A has completed one rotation when the pole pair number setter 222 has set pole pair numbers for the number of pole pairs in the ring magnet 20A and the peak value determiner 223 has determined the maximum value in the range of the electrical angle between 0 to 360 degrees within each pole pair.

In response to receiving, from the rotation determiner 224, a rotation signal that determines that the ring magnet 20A has completed one rotation, the origin pole pair detector 225 compares the peak values between the pole pairs and determines the pole pair with the maximum peak value as a pole pair including the characteristic magnetized section. The origin pole pair detector 225 stores the pole pair number of the pole pair with the maximum peak value into the storage 230 as the origin pole pair number.

The absolute mechanical-angle calculator 226 calculates, using Formula 3 above, the absolute mechanical angle of the ring magnet 20A based on the origin pole pair number, and the electrical angle and the pole pair number of the pole pair with the magnetic flux being detected by the magnetic detection unit 15a. The electrical angle calculated by the electrical angle calculator 221 is used for the electrical angle of the pole pair with the magnetic flux density being detected by the magnetic detection unit 15a. The pole pair number set by the pole pair number setter 222 is used for the pole pair number of the pole pair with the magnetic flux density being detected by the magnetic detection unit 15a. The absolute mechanical-angle calculator 226 may output the calculated absolute mechanical angle to a control device such as the controller CT that externally controls the rotator 16 with the ring magnet 20A. The absolute mechanical-angle calculator 226 may also calculate the relative mechanical angle of the ring magnet 20A using Formula 2 above.

The storage 230 may be a computer-readable recording medium. For example, the storage 230 may include at least one of a read-only memory (ROM) or a random-access memory (RAM). The storage 230 may include at least one of an erasable programmable read-only memory (RPROM) or an electrically erasable programmable read-only memory (EEPROM), in addition to the ROM or the RAM. The storage 230 may be referred to as a register, a cache, or a main memory. The storage 230 may also store, for example, a program and a software module (including a rotation angle detection program) executable to perform the processes in one embodiment of the present disclosure.

The storage 230 may store information output from the A/D converter 210 and may also input and output information to and from the control unit 220 and store the input or output information. The storage 230 may also store information exchanged between the functional blocks in the control unit 220. The storage 230 may also store information to be output from the control unit 220.

As described above, for a single pole pair in the ring magnet 20A, the magnetic detector 15al outputs a sine wave magnetic flux density detection signal, and the magnetic detector 15a2 outputs a cosine wave magnetic flux density detection signal. The ring magnet 20A includes a characteristic magnetized section. The rotation angle detector 200 with this structure can calculate and output the absolute mechanical angle of the ring magnet 20A. Flowchart of Example Schematic Operation Performed by Rotation Angle Detector

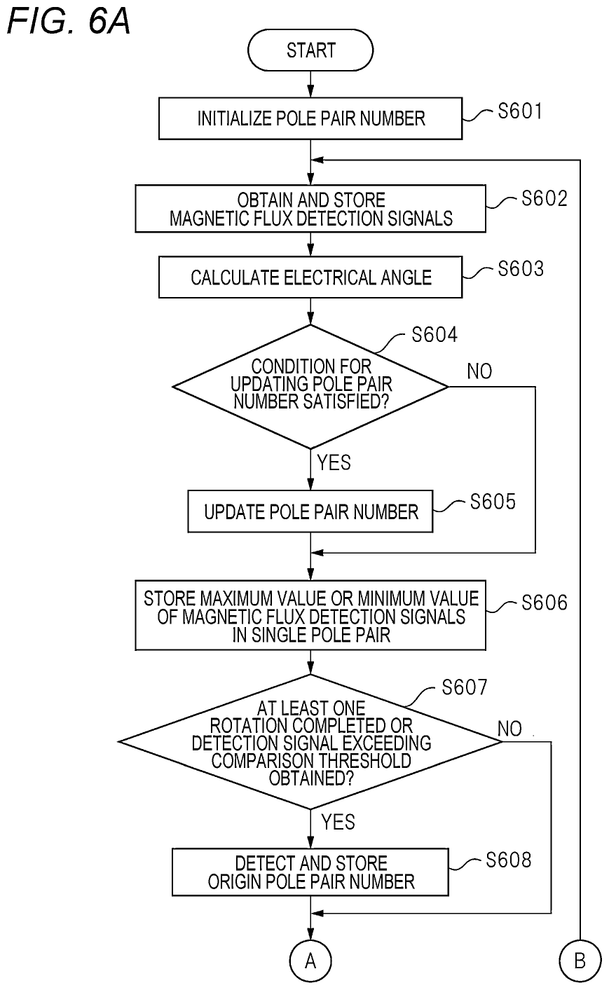

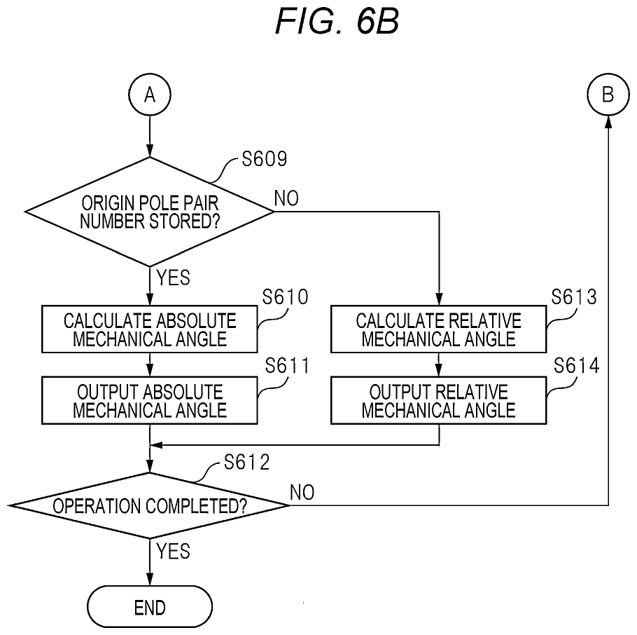

FIGS. 6A and 6B are flowcharts showing an example schematic operation performed by the rotation angle detector 200 according to the present embodiment.

In step S601, the pole pair number setter 222 initializes the pole pair number in response to the magnetic detection unit 15a and the rotation angle detector 200 being powered on. For example, the pole pair number setter 222 sets the pole pair number to 0 or to a predetermined integer in response to the magnetic detection unit 15a and the rotation angle detector 200 being powered on.

In step S602, the rotation angle detector 200 converts analog sine and cosine wave magnetic flux density detection signals output from the magnetic detection unit 15a to digital signals with the A/D converter 210. The rotation angle detector 200 stores the digital signals into the storage 230. The rotation angle detector 200 also outputs the digital signals to the electrical angle calculator 221.

In step S603, the electrical angle calculator 221 calculates, using Formula 1 above, the electrical angle based on the digital signal indicating the magnitude of the sine wave magnetic flux density detection signal and the digital signal indicating the magnitude of the cosine wave magnetic flux density detection signal. The electrical angle calculator 221 outputs the calculated electrical angle to the pole pair number setter 222.

In step S604, the pole pair number setter 222 determines whether to increment or decrement the pole pair number based on electrical angle information indicating the electrical angle input from the electrical angle calculator 221. For example, the pole pair number setter 222 determines that the condition for updating the pole pair number is satisfied when the electrical angle indicated by the electrical angle information has changed from 360 to 0 degrees or when the electrical angle indicated by the electrical angle information has changed from 0 to 360 degrees. When the condition for updating the pole pair number is satisfied (Yes in step S604), the pole pair number setter 222 advances to step S605. When the condition for updating the pole pair number is not satisfied (No in step S604), the pole pair number setter 222 advances to step S606.

In step S605, in response to the electrical angle indicated by the electrical angle information changing from 360 to 0 degrees, the pole pair number setter 222 increments the pole pair number by one. In response to the electrical angle indicated by the electrical angle information changing from 0 to 360 degrees, the pole pair number setter 222 decrements the pole pair number by one. When the resulting pole pair number exceeds the maximum pole pair number, the pole pair number setter 222 sets the pole pair number to 0. When the resulting pole pair number is a negative number, the pole pair number setter 222 sets the pole pair number to the maximum pole pair number. In this manner, the pole pair number setter 222 updates the pole pair number.

In step S606, the peak value determiner 223 determines, within the range of a single pole pair, the peak value of the sine wave magnetic flux detection signal and the cosine wave magnetic flux detection signal output from the A/D converter 210, and stores the peak value into the storage 230. The peak value indicates the maximum value or the minimum value. The peak value determined by the peak value determiner 223 indicates the maximum value or the minimum value depending on the magnetization method used to magnetize the characteristic magnetized section.

In step S607, the rotation determiner 224 determines whether the ring magnet 20A has completed one rotation or whether a detection signal exceeds a comparison threshold. For example, when the pole pair number set by the pole pair number setter 222 reaches the pole pair number obtained by subtracting one from the number of pole pairs of the ring magnet 20A, and the peak value determiner 223 has already determined the maximum value or the minimum value in the range of the electrical angle from 0 and 360 degrees in each pole pair, the rotation determiner 224 determines that the ring magnet 20A has completed one rotation. When the rotation determiner 224 determines that the ring magnet 20A has completed one rotation or that any detection signal exceeds the comparison threshold (Yes in step S607), the rotation angle detector 200 advances to step S608. When the rotation determiner 224 determines that the ring magnet 20A has yet to perform one rotation or that no detection signal exceeds the comparison threshold (No in step S607), the rotation angle detector 200 advances to step S609.

In step S608, the origin pole pair detector 225 compares the peak values between the pole pairs and determines the pole pair with the maximum peak value as a pole pair including the characteristic magnetized section. The origin pole pair detector 225 stores the pole pair number of the pole pair with the maximum peak value into the storage 230 as the origin pole pair number. In some cases, the origin pole pair detector 225 compares the peak values between the pole pairs and determines the pole pair with the minimum peak value as a pole pair including the characteristic magnetized section. The origin pole pair detector 225 can also store the pole pair number of the pole pair with the minimum peak value into the storage 230 as the origin pole pair number.

In step S609, the rotation angle detector 200 determines whether the origin pole pair number is stored in the storage 230 by the origin pole pair detector 225. When the origin pole pair number is stored in the storage 230 (Yes in step S609), the rotation angle detector 200 advances to step S610. When no origin pole pair number is stored in the storage 230 (No in step S609), the rotation angle detector 200 advances to step S613.

In step S610, the absolute mechanical-angle calculator 226 calculates, using Formula 3 above, the absolute mechanical angle of the ring magnet 20A based on the origin pole pair number, and the electrical angle and the pole pair number of the pole pair with the magnetic flux density being detected by the magnetic detection unit 15a. The electrical angle calculated by the electrical angle calculator 221 is used for the electrical angle of the pole pair with the magnetic flux being detected by the magnetic detection unit 15a. The pole pair number set by the pole pair number setter 222 is used for the pole pair number of the pole pair with the magnetic flux being detected by the magnetic detection unit 15a.

In step S611, the absolute mechanical-angle calculator 226 outputs, as the absolute mechanical angle, the calculated absolute mechanical angle to a control device such as the controller CT that externally controls the rotator 16 with the ring magnet 20A.

In step S612, the determination is performed as to whether the operation of the rotation angle detector 200 has been completed. When the operation of the rotation angle detector 200 has been completed (Yes in step S612), the rotation angle detector 200 ends the processing. When the operation of the rotation angle detector 200 has not been completed (No in step S612), the rotation angle detector 200 returns to step S602.

In step S613, the absolute mechanical-angle calculator 226 calculates, using Formula 2 above, the relative mechanical angle of the ring magnet 20A based on the electrical angle and the pole pair number of the pole pair with the magnetic flux density being detected by the magnetic detection unit 15a.

In step S614, the absolute mechanical-angle calculator 226 outputs, as the relative mechanical angle, the calculated relative mechanical angle to a control device such as the controller CT that externally controls the rotator 16 with the ring magnet 20A.

### Positional Relationship Between Magnetic Detector and Ring Magnet

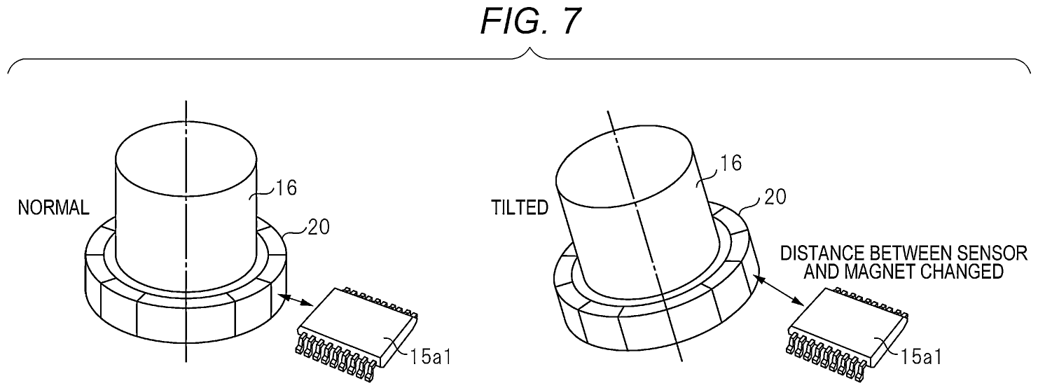

Referring to FIG. 7, the permissive positional relationship between the MR sensor 15a1 functioning as a magnetic detector and a ring magnet 20 will now be described. The ring magnet 20A and ring magnets 20B to 20L in modifications (described later) are collectively referred to as the ring magnet 20. The MR sensor 15a2 is located in the same manner as the MR sensor 15a1 and will not be described.

The MR sensor 15a1 and the ring magnet 20 in the left part of FIG. 7 face each other in the radial direction of the ring magnet 20 as shown in FIG. 1. The rotation angle detector 200 according to the present embodiment compares the relative values of the magnitudes of the magnetic fluxes of the magnetized sections in the ring magnet 20. Thus, the position of the MR sensor 15a1 is not limited to the position shown in FIG. 1 and in the left part of FIG. 7.

For example, when the distance between the MR sensor 15a1 and the ring magnet changes over time as shown in the right part of FIG. 7 but still allows the magnetic flux of the ring magnet 20 to be detected, the rotation angle detector 200 according to the present embodiment can calculate the absolute mechanical angle. When the angle between the MR sensor 15a1 and the rotation central axis of the ring magnet 20 changes over time as shown in the right part of FIG. 7 but still allows the magnetic flux of the ring magnet 20 to be detected, the rotation angle detector 200 according to the present embodiment can calculate the absolute mechanical angle. When the MR sensor 15a1 and the ring magnet 20 have the initial positional relationship shown in the right part of FIG. 7, but the positional relationship still allows the magnetic flux of the ring magnet 20 to be detected, the rotation angle detector 200 according to the present embodiment can calculate the absolute mechanical angle.

As described above, for a single pole pair in the ring magnet 20, the magnetic detector 15a1 outputs a sine wave magnetic flux density detection signal, and the magnetic detector 15a2 outputs a cosine wave magnetic flux density detection signal. The ring magnet includes a characteristic magnetized section. The rotation angle detector 200 with this structure can calculate and output the absolute mechanical angle of the ring magnet 20.

The rotation angle detector 200 can thus detect both the rotation angle and the origin of the hollow shaft 16 using the single ring magnet 20 and the pair of MR sensors 15a1 and 15a2. The rotation angle detector 200 is thus smaller and less expensive and has higher detection accuracy.

### First Modification of First Embodiment

A first modification of the first embodiment will now be described in detail with reference to the drawings. Like reference numerals denote like functional elements in the above first embodiment. Such elements will not be described.

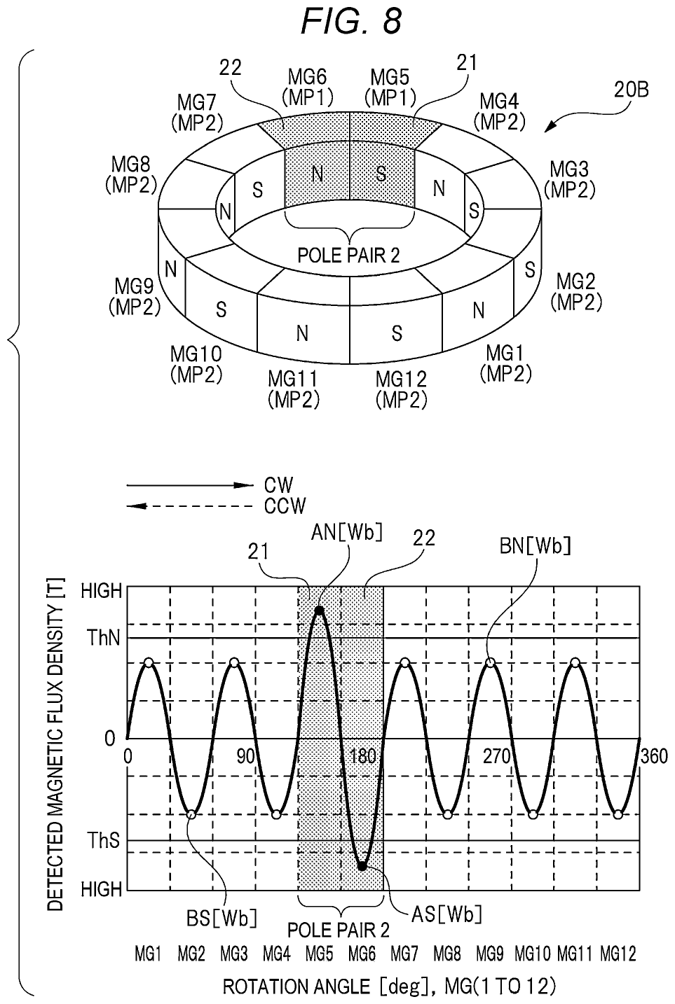

FIG. 8 shows a ring magnet in the first modification of the first embodiment and the magnetic flux density detected with the ring magnet. For the detected magnetic flux density, the sine wave alone is shown, and the cosine wave is not shown and will not be described.

As shown in FIG. 8, a ring magnet 20B in the first modification of the first embodiment includes a magnetized section MG6 (shaded part in the figure) adjacent to a magnetized section MG5 (origin-indicator magnetized section 21), of 12 magnetized sections MG1 to MG12, serving as an origin-indicator magnetized section 22 (strongly magnetized section), unlike the ring magnet 20A in the first embodiment (refer to FIG. 3).

In other words, in the first modification of the first embodiment, a pair of adjacent magnetized sections MG5 and MG6 with different poles, of the multiple (12) magnetized sections MG1 to MG12, serve as the origin-indicator magnetized sections 21 and 22.

In this structure, the MR sensor 15a (refer to FIG. 1) facing the ring magnet 20B detects a sinusoidal magnetic flux as shown in the lower graph in FIG. 8. More specifically, the MR sensor 15a detects a higher magnetic flux density when facing the origin-indicator magnetized section 21 or 22 (magnetized section MG5 or MG6) than when facing any one of the other N- and S-polar magnetized sections MG1 to MG4 and MG7 to MG12, as shown in the shaded area in the graph. In the figure, the magnetic flux density levels AN and AS (T) detected at the black-dotted peaks (marked with black dots at two points) are each about 1.5 times higher than the magnetic flux density level BN or BS (T) detected at the other white-dotted peaks (marked with white dots at ten points) (AN≈1.5×BN and AS≈1.5×BS). Specifically, when the magnetic flux density levels AN and AS (T) detected at the points marked with black dots represent a ripple of 100%, the magnetic flux density levels BN and BS (T) detected at the points marked with white dots represent a ripple of about 90% (a ripple difference is about 10%).

Thus, the rotation angle detector 200 detecting any one of the two outstanding peak points (marked with black dots) can detect the origin or reference point of rotation of the hollow shaft 16.

When the detected magnetic flux density level AS (T) is used, the rotation angle detector 200 compares the detected magnetic flux density level AS (T) as the major peak value (marked with a black dot) and the detected magnetic flux density level BS (T) as the minor peak value (marked with a white dot) with a comparison threshold ThS (T) stored in the storage 230 in the rotation angle detector 200 (AS>ThS>BS). The controller CT thus detects the single major S-polar peak value (marked with a black dot) between 0 and 360 degrees and determines that the detected peak indicates the origin of the hollow shaft 16.

### Second Modification of First Embodiment

A second modification of the first embodiment will now be described in detail with reference to the drawings. Like reference numerals denote like functional elements in the above first embodiment. Such elements will not be described.

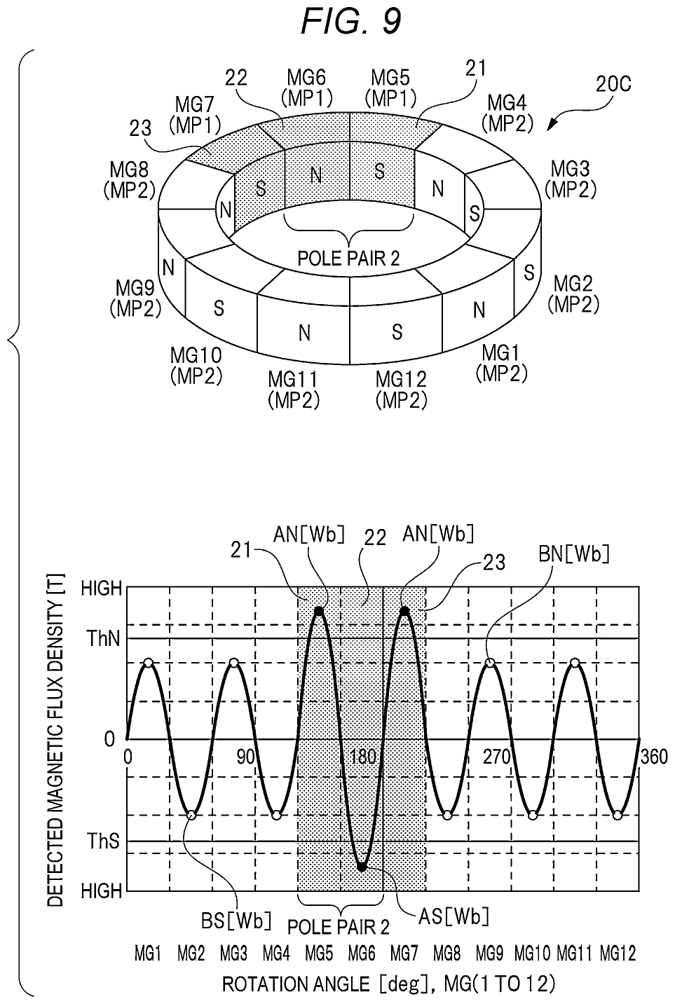

FIG. 9 shows a ring magnet in the second modification of the first embodiment and the magnetic flux density detected with the ring magnet. For the detected magnetic flux density, the sine wave alone is shown, and the cosine wave is not shown and will not be described.

As shown in FIG. 9, a ring magnet 20C in the second modification of the first embodiment includes magnetized sections MG6 and MG7 (shaded part in the figure) adjacent to a magnetized section MG5 (origin-indicator magnetized section 21), of 12 magnetized sections MG1 to MG12, serving as origin-indicator magnetized sections 22 and 23 (strongly magnetized sections), unlike the ring magnet 20A in the first embodiment (refer to FIG. 3).

In this structure, the MR sensor 15a (refer to FIG. 1) facing the ring magnet 20C detects a sinusoidal magnetic flux as shown in the lower graph in FIG. 9. More specifically, the MR sensor 15a detects a higher magnetic flux density when facing the origin-indicator magnetized section 21, 22, or 23 (magnetized section MG5, MG6, or MG7) than when facing any one of the other N- and S-polar magnetized sections MG1 to MG4 and MG8 to MG12, as shown in the shaded area in the graph. In the figure, each of the magnetic flux density levels detected at the black-dotted peaks (AN in T marked with black dots at two points and AS in T marked with a black dot at one point) is about 1.5 times higher than the magnetic flux density levels detected at the other white-dotted peaks (BN or BS in T marked with white dots at nine points) (AN≈1.5×BN, AS≈1.5×BS). Specifically, when the magnetic flux density levels AN and AS (T) detected at the points marked with black dots represent a ripple of 100%, the magnetic flux density levels BN and BS (T) detected at the points marked with white dots represent a ripple of about 90% (a ripple difference is about 10%).

In this case, the rotation angle detector 200 detecting the magnetic flux density level AS (T) at the single point can detect the origin or reference point of rotation of the hollow shaft 16. More specifically, the rotation angle detector 200 compares the detected magnetic flux density level AS (T) as the major peak value (marked with a black dot) and the detected magnetic flux density level BS (T) as the minor peak value (marked with a white dot) with the comparison threshold ThS (T) stored in the storage 230 in the rotation angle detector 200 (AS>ThS>BS). The rotation angle detector 200 thus detects the single major S-polar peak value (marked with a black dot) between 0 and 360 degrees and determines that the detected peak indicates the origin of the hollow shaft 16.

The above structure in the second modification of the first embodiment also produces the same advantageous effects as in the above first embodiment. In the second modification of the first embodiment, in addition to this, the magnetized sections MG5 and MG7 adjacent to the origin-indicator magnetized section 22 (magnetized section MG6) also serve as the origin-indicator magnetized sections 21 and 23 (strongly magnetized sections). Thus, the rotation angle detector 200 determines that the hollow shaft 16 is in the range of rotation angles from 120 to 210 degrees (range of absolute mechanical angles from 0 to 90 degrees) by continuously detecting the magnetic flux density level AN (T) at the major peak value (marked with a black dot) exceeding the comparison threshold ThN (T), then the magnetic flux density level AS (T) at the major peak value (marked with a black dot) exceeding the comparison threshold ThS (T), and finally the magnetic flux density level AN (T) at the major peak value (marked with a black dot) exceeding the comparison threshold ThN (T). The rotation angle detector 200 can further predict the origin (magnetic flux density level AS in T at a major peak value) by detecting one of the magnetic flux density levels AN in T at the major peak value. The rotation angle detector 200 can output rotation direction information about the rotation direction of the hollow shaft 16 to an external device together with absolute mechanical angle information indicating the absolute mechanical angle.

### Third and Fourth Modifications of First Embodiment

Third and fourth modifications of the first embodiment will now be described in detail with reference to the drawings. Like reference numerals denote like functional elements in the above first embodiment. Such elements will not be described.

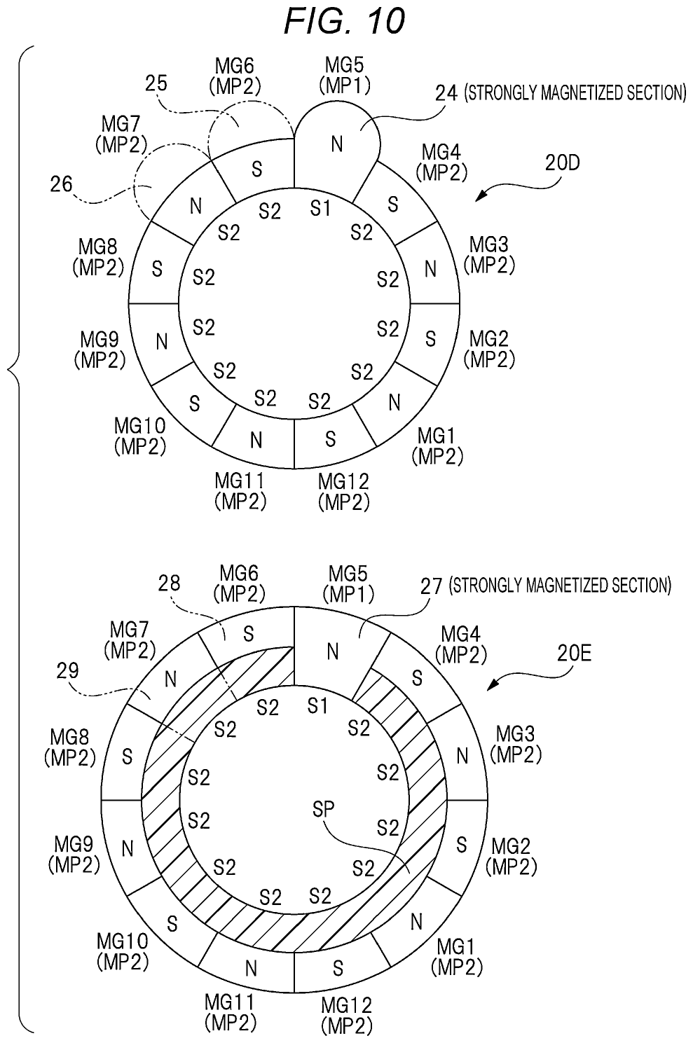

FIG. 10 is a schematic view of ring magnets in the third and fourth modifications of the first embodiment.

As shown in FIG. 10, a ring magnet 20D in the third modification of the first embodiment and a ring magnet 20E in the fourth modification of the first embodiment each include a magnetized section MG5 (origin-indicator magnetized section 24 or 27), of 12 magnetized sections MG1 to MG12, with a shape different from the shape of each of the other magnetized sections MG1 to MG4 and MG6 to MG12, unlike the ring magnet 20A in the first embodiment (refer to FIG. 3). The symbols N and S in FIG. 10 indicate the polarity at the radially outer ends of the ring magnets 20D and 20E.

More specifically, in the ring magnet 20D (outward protrusion type) in the third modification of the first embodiment, the origin-indicator magnetized section 24 (magnetized section MG5) protrudes radially outward from the ring magnet 20D, and has a volume S1 larger than a volume S2 of each of the other magnetized sections MG1 to MG4 and MG6 to MG12 (S1>S2). Thus, magnetizing the ring magnet 20D using a magnetizer causes the magnetic force MP1 from the magnetized section MG5 to be larger than the magnetic forces MP2 from the other magnetized sections MG1 to MG4 and MG6 to MG12.

The magnetizer for magnetizing the ring magnet 20D (outward protrusion type) includes a total of 12 magnetic force generators each corresponding to one of the magnetized sections MG1 to MG12 in the ring magnet 20D. The coils in these magnetic force generators each have the same number of turns (turns). This allows the use of a general-purpose magnetizer with a simple structure.

To obtain the same characteristics as those in the first and second modifications of the first embodiment above, the magnetized sections MG6 and MG7 may also protrude radially outward to serve as origin-indicator magnetized sections 25 and 26 (strongly magnetized sections), as indicated by the two-dot-dash lines in the figure.

In the ring magnet 20E (inward protrusion type) in the fourth modification of the first embodiment, the origin-indicator magnetized section 27 (magnetized section MG5) protrudes radially inward from the ring magnet 20E, and has a volume S1 larger than a volume S2 of each of the other magnetized sections MG1 to MG4 and MG6 to MG12 (S1>S2). Thus, magnetizing the ring magnet 20E using a magnetizer causes the magnetic force MP1 from the magnetized section MG5 to be larger than the magnetic forces MP2 from the other magnetized sections MG1 to MG4 and MG6 to MG12.

As a magnetizer for magnetizing the ring magnet 20E (inner protrusion type) as well, a general-purpose magnetizer with a simple structure may be used as for the ring magnet 20D in the third modification of the first embodiment. A resin (non-magnetic) spacer SP is attached to the radially inner end of the ring magnet 20E. Thus, the ring magnet 20E is fixed to the hollow shaft 16 (refer to FIG. 1) without rattling.

To obtain the same characteristics as those in the first embodiment and the first and second modifications of the first embodiment above, the magnetized sections MG6 and MG7 may also protrude radially inward to serve as origin-indicator magnetized sections 28 and 29 (strongly magnetized sections), as indicated by the two-dot-dash lines in the figure.

The above structures in the third and fourth modifications of the first embodiment also produce substantially the same advantageous effects as in the above first embodiment.

### Fifth Modification of First Embodiment

A fifth modification of the first embodiment will now be described in detail with reference to the drawings. Like reference numerals denote like functional elements in the above first embodiment. Such elements will not be described.

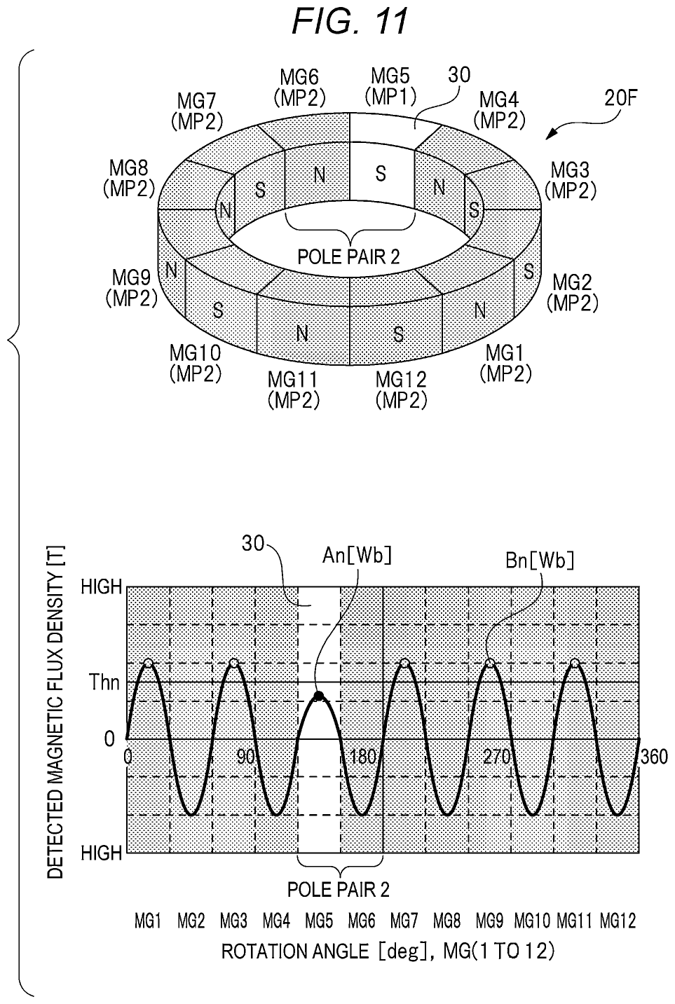

FIG. 11 shows a ring magnet in the fifth modification of the first embodiment and the magnetic flux density detected with the ring magnet. For the detected magnetic flux density, the sine wave alone is shown, and the cosine wave is not shown and will not be described.

As shown in FIG. 11, a ring magnet 20F in the fifth modification of the first embodiment includes a magnetized section MG5 (outlined area in the figure), of 12 magnetized sections MG1 to MG12, serving as an origin-indicator magnetized section 30 (weakly magnetized section), unlike the ring magnet 20A in the first embodiment (refer to FIG. 3). In other words, in the fifth modification of the first embodiment, the magnitudes of the magnetic forces are in a relationship opposite to the relationship in the first embodiment.

The origin-indicator magnetized section 30 (magnetized section MG5) generates a (small) magnetic flux indicating that the hollow shaft 16 has completed one rotation. More specifically, the origin-indicator magnetized section 30 has a magnetic force different from the magnetic force from each of the other magnetized sections MG1 to MG4 and MG6 to MG12, which is smaller than the magnetic forces from the other magnetized sections MG1 to MG4 and MG6 to MG12. In other words, the magnetic force MP1 from the magnetized section MG5 is smaller than the magnetic forces MP2 from the other magnetized sections MG1 to MG4 and MG6 to MG12 (MP1<MP2). The magnetized sections MG1 to MG12 including the origin-indicator magnetized section 30 (magnetized section MG5) each have the same volume.

In this structure, the MR sensor 15a (refer to FIG. 1) facing the ring magnet 20F detects a sinusoidal magnetic flux as shown in the lower graph in FIG. 11. More specifically, the MR sensor 15a detects a lower magnetic flux density when facing the origin-indicator magnetized section 30 (magnetized section MG5) than when facing any one of the other N-polar magnetized sections MG1, MG3, MG7, MG9, and MG11, as shown in the outlined area in the graph. In the figure, the magnetic flux density level An (T) detected at the black-dotted peak (marked with a black dot at one point) is about a half (½) of the magnetic flux density level Bn (T) detected at the other white-dotted peaks (marked with white dots at five points) (An≈0.5×Bn). Specifically, when the magnetic flux density level Bn (T) detected at the points marked with white dots represents a ripple of 100%, the magnetic flux density level An (T) detected at the point marked with a black dot represents a ripple of about 90% (a ripple difference is about 10%).

Thus, the rotation angle detector 200 detecting the single minor peak point marked with a black dot can detect the origin or reference point of rotation of the hollow shaft 16. More specifically, the rotation angle detector 200 compares the detected magnetic flux density level An (T) as the minor peak value (marked with a black dot) and the detected magnetic flux density level Bn (T) as the major peak value (marked with a white dot) with a comparison threshold Thn (T) stored in the storage 230 in the rotation angle detector 200 (An<Thn<Bn). The controller CT thus detects the single minor N-polar peak value (marked with a black dot) between 0 and 360 degrees and determines that the detected peak indicates the origin of the hollow shaft 16.

The single minor peak value between 0 and 360 degrees may be an S-polar peak instead of an N-polar peak. The rotation angle detector 200 can detect the origin of the hollow shaft 16 as well. The magnetic forces from the magnetized sections MG1 to MG12 decrease as the temperature changes. Thus, the rotation angle detector 200 may adjust the comparison threshold Thn based on temperature changes.

The above structure in the fifth modification of the first embodiment also produces substantially the same advantageous effects as in the above first embodiment. However, in a magnetizer used for magnetizing the ring magnet 20F in the fifth modification of the first embodiment, the coil of the magnetic force generator for the magnetized section MG5 has a smaller number of turns than the coils of the magnetic force generators for the other magnetized sections MG1 to MG4 and MG6 to MG12, in a manner opposite to the first embodiment. Any structure may be used when the magnetic force generated by the magnetic force generator for the magnetized section MG5 is smaller than the other sections. The magnetic force generator for the magnetized section MG5 may have no coil wound. In this case, the magnetized section MG5 is weakly magnetized by leakage flux from the magnetic force generators for the magnetized sections MG4 and MG6.

### Sixth Modification of First Embodiment

A sixth modification of the first embodiment will now be described in detail with reference to the drawings. Like reference numerals denote like functional elements in the above fifth modification of the first embodiment. Such elements will not be described.

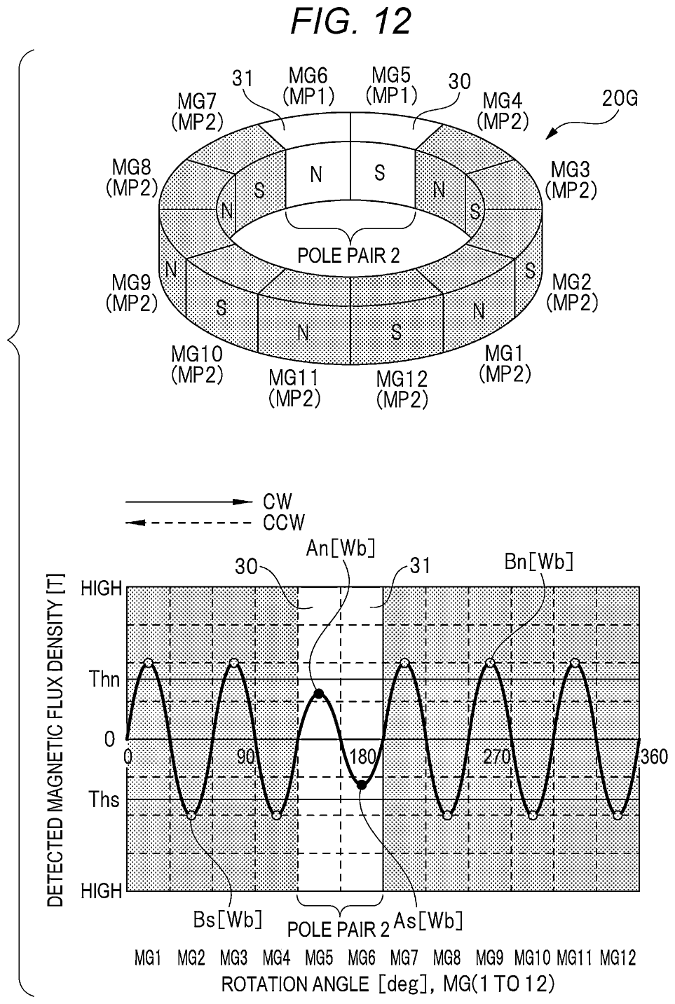

FIG. 12 shows a ring magnet in the sixth modification of the first embodiment and the magnetic flux density detected with the ring magnet. For the detected magnetic flux density, the sine wave alone is shown, and the cosine wave is not shown and will not be described.

As shown in FIG. 12, a ring magnet 20G in the sixth modification of the first embodiment includes a magnetized section MG6 (outlined area in the figure) adjacent to a magnetized section MG5 (origin-indicator magnetized section 30), of 12 magnetized sections MG1 to MG12, serving as an origin-indicator magnetized section 31 (weakly magnetized section), unlike the ring magnet 20F in the fifth modification of the first embodiment (refer to FIG. 11).

In other words, in the sixth modification of the first embodiment, a pair of adjacent magnetized sections MG5 and MG6 with different poles, of the multiple (12) magnetized sections MG1 to MG12, serve as the origin-indicator magnetized sections 30 and 31.

In this structure, the MR sensor 15a (refer to FIG. 1) facing the ring magnet 20G detects a sinusoidal magnetic flux as shown in the lower graph in FIG. 12. More specifically, the MR sensor 15a detects a lower magnetic flux density when facing the origin-indicator magnetized section 30 or 31 (magnetized section MG5 or MG6) than when facing any one of the other N- and S-polar magnetized sections MG1 to MG4 and MG7 to MG12, as shown in the outlined area in the graph. In the figure, the magnetic flux density levels An and As (T) detected at the black-dotted peaks (marked with black dots at two points) are each about a half (½) of the magnetic flux density level Bn or Bs (T) detected at the other white-dotted peaks (marked with white dots at ten points) (An≈0.5×Bn, As≈0.5×Bs). Specifically, when the magnetic flux density levels Bn and Bs (T) detected at the points marked with white dots represent a ripple of 100%, the magnetic flux density levels An and As (T) detected at the points marked with black dots represent a ripple of about 90% (a ripple difference is about 10%).

Thus, the rotation angle detector 200 detecting any one of the two minor peak points marked with black dots can detect the origin or reference point of rotation of the hollow shaft 16.

When the detected magnetic flux density level As (T) is used, the rotation angle detector 200 compares the detected magnetic flux density level As (T) as the minor peak value (marked with a black dot) and the detected magnetic flux density level Bs (T) as the major peak value (marked with a white dot) with a comparison threshold Ths (T) stored in the storage 230 in the rotation angle detector 200 (As<Ths<Bs). The rotation angle detector 200 thus detects the single minor S-polar peak value (marked with a black dot) between 0 and 360 degrees and determines that the detected peak indicates the origin of the hollow shaft 16.

### Seventh Modification of First Embodiment

A seventh modification of the first embodiment will now be described in detail with reference to the drawings. Like reference numerals denote like functional elements in the above fifth modification of the first embodiment. Such elements will not be described.

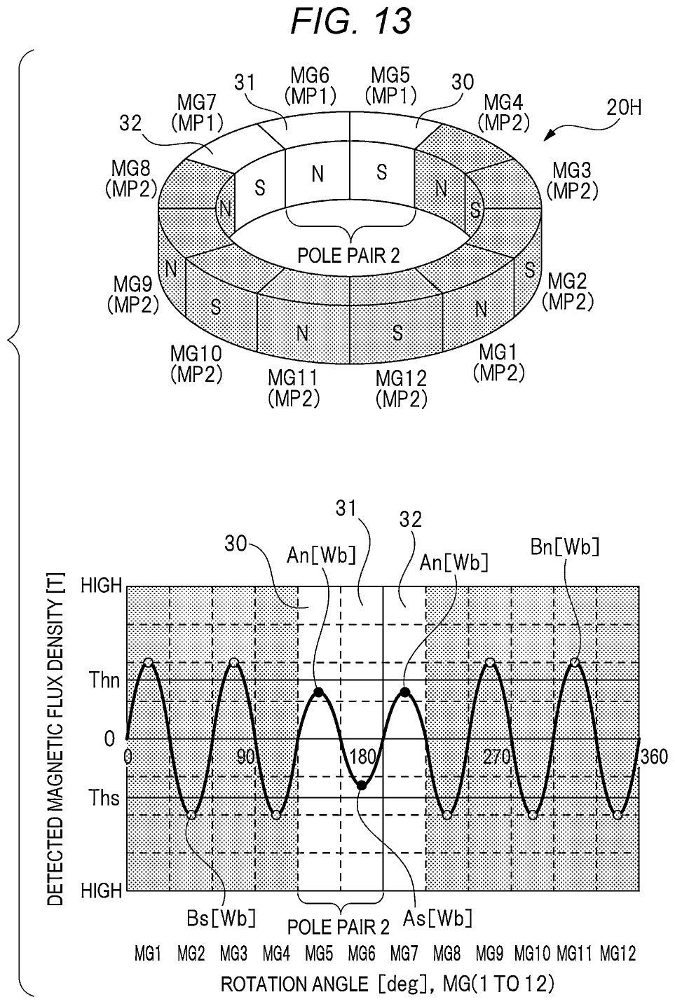

FIG. 13 shows a ring magnet in the seventh modification of the first embodiment and the magnetic flux density detected with the ring magnet.

As shown in FIG. 13, a ring magnet 20H in the seventh modification of the first embodiment includes magnetized sections MG6 and MG7 (outlined area in the figure) adjacent to a magnetized section MG5 (origin-indicator magnetized section 30), of 12 magnetized sections MG1 to MG12, serving as the origin-indicator magnetized sections 31 and 32 (weakly magnetized sections), unlike the ring magnet 20F in the fifth modification of the first embodiment (refer to FIG. 11).

In this structure, the MR sensor 15a (refer to FIG. 1) facing the ring magnet 20H detects a sinusoidal magnetic flux as shown in the lower graph in FIG. 13. More specifically, the MR sensor 15a detects a lower magnetic flux density when facing the origin-indicator magnetized section 30, 31, or 32 (magnetized section MG5, MG6, or MG7) than when facing any one of the other N- and S-polar magnetized sections MG1 to MG4 and MG8 to MG12, as shown in the outlined area in the graph. In the figure, the magnetic flux density levels detected at the black-dotted peaks (An in T marked with black dots at two points and As in T marked with a black dot at one point) are each about a half (½) of the magnetic flux density levels detected at the other white-dotted peaks (Bn or Bs in T with white dots at nine points) (An≈0.5×Bn, As≈0.5×Bs). Specifically, when the magnetic flux density levels Bn and Bs (T) detected at the points marked with white dots represent a ripple of 100%, the magnetic flux density levels An and As (T) detected at the points marked with black dots represent a ripple of about 90% (a ripple difference is about 10%).

In this case, the rotation angle detector 200 detecting the magnetic flux density level As (T) at the single point can detect the origin or reference point of rotation of the hollow shaft 16. More specifically, the rotation angle detector 200 compares the detected magnetic flux density level As (T) as the minor peak value (marked with a black dot) and the detected magnetic flux density level Bs (T) as the major peak value (marked with a white dot) with the comparison threshold Ths (T) stored in the storage 230 in the rotation angle detector 200 (As<Ths<Bs). The rotation angle detector 200 thus detects the single minor S-polar peak value (marked with a black dot) between 0 and 360 degrees and determines that the detected peak indicates the origin of the hollow shaft 16.

The above structure in the seventh modification of the first embodiment also produces substantially the same advantageous effects as in the above fifth modification of the first embodiment. In the seventh modification of the first embodiment, in addition to this, the magnetized sections MG5 and MG7 adjacent to the origin-indicator magnetized section 31 (magnetized section MG6) also serve as the origin-indicator magnetized sections 30 and 32 (weakly magnetized sections). Thus, the rotation angle detector 200 determines that the hollow shaft 16 is in the range of rotation angles from 120 to 210 degrees by continuously detecting the magnetic flux density level An (T) at the minor peak value (marked with a black dot) (without exceeding the comparison threshold Thn in T), then the magnetic flux density level As (T) at the minor peak value (marked with a black dot) (without exceeding the comparison threshold Ths in T), and finally the magnetic flux density level An (T) at the minor peak value (marked with a black dot) (without exceeding the comparison threshold Thn in T). The rotation angle detector 200 can also predict the origin (magnetic flux density level As in T at a minor peak value) by detecting one of the magnetic flux density levels An (T) at the minor peak value.

### Eighth and Ninth Modifications of First Embodiment

Eighth and ninth modifications of the first embodiment will now be described in detail with reference to the drawings. Like reference numerals denote like functional elements in the above fifth modification of the first embodiment. Such elements will not be described.

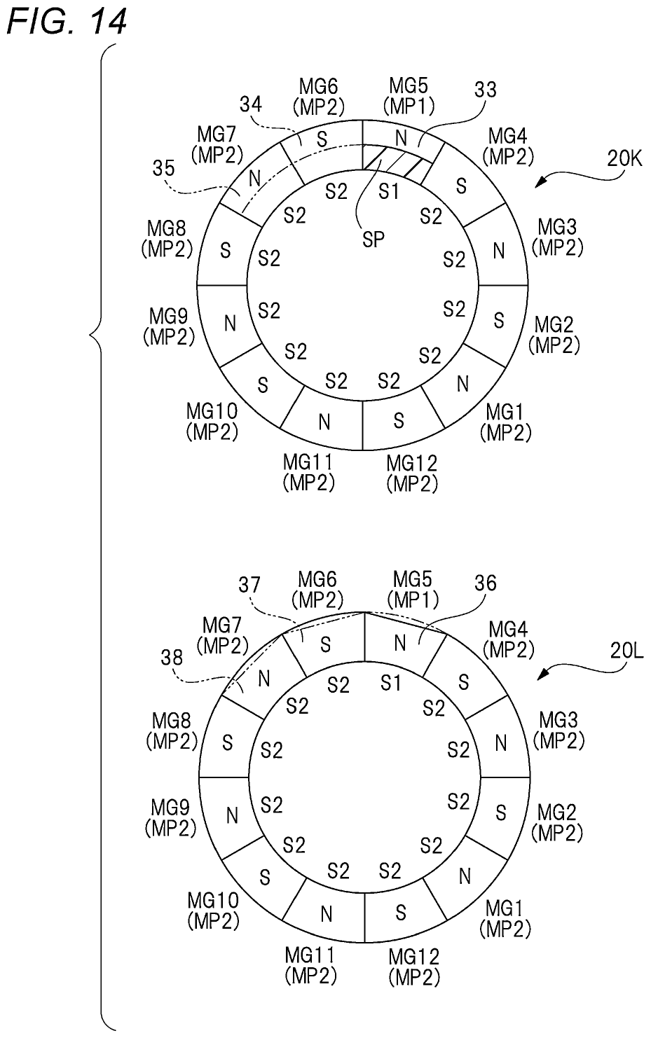

FIG. 14 is a schematic view of ring magnets in the eighth and ninth modifications of the first embodiment.

As shown in FIG. 14, a ring magnet 20K in the eighth modification of the first embodiment and a ring magnet 20L in the ninth modification of the first embodiment each include a magnetized section MG5 (origin-indicator magnetized section 33 or 36), of 12 magnetized sections MG1 to MG12, with a shape different from the shape of each of the other magnetized sections MG1 to MG4 and MG6 to MG12, unlike the ring magnet 20F in the fifth modification of the first embodiment (refer to FIG. 11). The symbols N and S in FIG. 14 indicate the polarity at the radially outer end of the ring magnets 20K and 20L.

More specifically, in the ring magnet 20K (inner recess type) in the eighth modification of the first embodiment, the origin-indicator magnetized section 33 (magnetized section MG5) is recessed radially outward into the ring magnet 20K, and has a volume S1 smaller than a volume S2 of each of the other magnetized sections MG1 to MG4 and MG6 to MG12 (S1<S2). Thus, magnetizing the ring magnet 20K using a magnetizer causes the magnetic force MP1 from the magnetized section MG5 to be smaller than the magnetic forces MP2 from the other magnetized sections MG1 to MG4 and MG6 to MG12.

The magnetizer for magnetizing the ring magnet 20K (inner recess type) includes a total of 12 magnetic force generators each corresponding to one of the magnetized sections MG1 to MG12 in the ring magnet 20K. The coils in these magnetic force generators each have the same number of turns (turns). This allows the use of a general-purpose magnetizer with a simple structure.

To obtain the same characteristics as those in the sixth and seventh modifications of the first embodiment above, magnetized sections MG6 and MG7 may also be recessed radially outward to serve as origin-indicator magnetized sections 34 and 35 (weakly magnetized sections), as indicated by the two-dot-dash lines in the figure.

A resin (non-magnetic) spacer SP is attached to the radially inner end of the origin-indicator magnetized section 33. Thus, the ring magnet 20K is fixed to the hollow shaft 16 (refer to FIG. 1) without rattling.

In the ring magnet 20L (outer cut type) in the ninth modification of the first embodiment, an outer peripheral portion of the origin-indicator magnetized section 36 (magnetized section MG5) is cut by a predetermined volume (shown by the two-dot-dash line in the figure) into a flat surface. Thus, the origin-indicator magnetized section 36 (magnetized section MG5) has a volume S1 smaller than a volume S2 of any one of the other magnetized sections MG1 to MG4 and MG6 to MG12 (S1<S2). Thus, magnetizing the ring magnet 20L using a magnetizer causes the magnetic force MP1 from the origin-indicator magnetized section MG5 to be smaller than the magnetic forces MP2 from the other magnetized sections MG1 to MG4 and MG6 to MG12.

As a magnetizer for magnetizing the ring magnet 20L (outer cut type) as well, a general-purpose magnetizer with a simple structure may be used as for the ring magnet 20K in the eighth modification of the first embodiment.

To obtain the same characteristics as those in the sixth and seventh modifications of the first embodiment above, outer peripheral portions of the magnetized sections MG6 and MG7 may also be cut into flat surfaces to allow these magnetized sections to serve as origin-indicator magnetized sections 37 and 38 (weakly magnetized sections), as indicated by the two-dot-dash lines in the figure.

The above structures in the eighth and ninth modifications of the first embodiment also produce substantially the same advantageous effects as in the above fifth modification of the first embodiment.

The present disclosure is not limited to the above embodiments, but may be modified variously without departing from the spirit and scope of the present disclosure. For example, although the above embodiments are described using the 12-pole ring magnets 20A to 20L, the number of poles used in the embodiments of the present disclosure is not limited to this number and may be reduced to 8 or increased to 14 or more, for example, as appropriate for the specifications used for the rotation angle detector 200. For example, the above embodiments are described in detail for ease of explanation of the present disclosure, and not all the described components may be included in each embodiment. Some of the components in the above embodiments may be eliminated or replaced, or other components may be added.

Although a magnetic sensor is used as an MR sensor in the above embodiments, the type of the sensor used in the embodiments of the present disclosure is not limited to this type of sensor and may be any other types of magnetic sensors, such as anisotropic magnetoresistive (AMR) sensors, giant magnetoresistive (GMR) sensors, and Hall sensors.

The above components, functions, processors, and processing units may each be partly or entirely implemented by hardware by, for example, being designed in an IC. The above components and functions may each be implemented by software with a processor interpreting and executing programs for implementing the functions. Information about, for example, the programs for implementing the functions, tables, and files may be stored in a storage device such as a memory, a hard disk drive, or a solid-state drive (SSD) or a recording medium such as an IC card, a secure digital (SD) card, or a digital versatile disc (DVD).

In the above drawings, control lines and information lines are selectively shown for explanatory purposes, and some of the control lines or the information lines may not be shown. Almost all the components may actually be connected to one another.

The materials, shapes, dimensions, numbers, and positions of the components in the above embodiments may be determined as appropriate to achieve the aspects of the present disclosure without being limited to the above embodiments.

What is claimed is:

1. A rotation angle detector for detecting a rotation angle of a rotator, the rotator including at least two pole pairs arranged in a ring, the rotation angle detector comprising:
an electrical angle calculator configured to calculate an electrical angle of the rotator based on a change in a magnetic flux of each of the at least two pole pairs;
a pole pair number setter configured to set a pole pair number for each of the at least two pole pairs in the rotator based on the electrical angle;
an origin pole pair detector configured to detect, based on magnitudes of magnetic fluxes of the at least two pole pairs, an origin pole pair as an origin and detect the pole pair number set for the origin pole pair as an origin pole pair number; and
an absolute mechanical-angle calculator configured to calculate an absolute mechanical angle of the rotator based on the electrical angle, the pole pair number, and the origin pole pair number.

2. The rotation angle detector according to claim 1, wherein
the electrical angle calculator calculates the electrical angle for each of the at least two pole pairs based on a sine wave electric signal of one cycle and a cosine wave electric signal of one cycle indicating a change in the magnetic flux of each of the at least two pole pairs.

3. The rotation angle detector according to claim 1, further comprising:
a rotation determiner configured to determine whether the rotator has performed one rotation based on the number of the at least two pole pairs and the electrical angle for each of the at least two pole pairs,
wherein the origin pole pair detector detects, after the rotator performs one rotation, at least one of a positive maximum value or a negative maximum value based on a plurality of peak values of a sine wave electric signal or of a cosine wave electric signal, detects the origin pole pair based on at least one of the positive maximum value or the negative maximum value, and detects the pole pair number set for the origin pole pair.

4. The rotation angle detector according to claim 1, further comprising:
a rotation determiner configured to determine whether the rotator has performed one rotation based on the number of the at least two pole pairs and the electrical angle for each of the at least two pole pairs,
wherein the origin pole pair detector detects, after the rotator performs one rotation, at least one of a positive minimum value or a negative minimum value based on a plurality of peak values of a sine wave electric signal or of a cosine wave electric signal, detects the origin pole pair based on at least one of the positive minimum value or the negative minimum value, and detects the pole pair number set for the origin pole pair.

5. The rotation angle detector according to claim 3, wherein
a maximum value of a magnitude of a magnetic flux of one magnet in the origin pole pair or two magnets with different poles in the origin pole pair is greater than maximum values of magnitudes of magnetic fluxes of other magnets.

6. The rotation angle detector according to claim 4, wherein
a maximum value of a magnitude of a magnetic flux of one magnet in the origin pole pair or two magnets with different poles in the origin pole pair is less than maximum values of magnitudes of magnetic fluxes of other magnets.

7. A rotation angle detection method to be used by a rotation angle detector for detecting a rotation angle of a rotator, the rotator including at least two pole pairs arranged in a ring, the rotation angle detection method comprising:
calculating an electrical angle of the rotator based on a change in a magnetic flux of each of the at least two pole pairs;
setting a pole pair number for each of the at least two pole pairs in the rotator based on the electrical angle;
detecting, based on magnitudes of magnetic fluxes of the at least two pole pairs, an origin pole pair as an origin and detecting the pole pair number set for the origin pole pair as an origin pole pair number; and
calculating an absolute mechanical angle of the rotator based on the electrical angle, the pole pair number, and the origin pole pair number.

8. A program executable by a computer included in a rotation angle detector for detecting a rotation angle of a rotator, the rotator including at least two pole pairs arranged in a ring, the program being a program for causing the computer to perform operations comprising:
calculating an electrical angle of the rotator based on a change in a magnetic flux of each of the at least two pole pairs;
setting a pole pair number for each of the at least two pole pairs in the rotator based on the electrical angle;
detecting, based on magnitudes of magnetic fluxes of the at least two pole pairs, an origin pole pair as an origin and detecting the pole pair number set for the origin pole pair as an origin pole pair number; and
calculating an absolute mechanical angle of the rotator based on the electrical angle, the pole pair number, and the origin pole pair number.

9. A rotation angle detection system, comprising:
the rotation angle detector according to claim 1;
a ring magnet rotatable together with the rotator, the ring magnet including a plurality of magnetized sections having different poles and being alternately arranged in a direction of rotation of the rotator, the plurality of magnetized sections including, as pole pairs, a plurality of pairs of adjacent magnetized sections having different poles;
the rotator including the ring magnet circumferentially on a rotational shaft; and
a magnetic flux detector configured to output a change in a magnetic flux of each of the pole pairs as a sine wave electric signal of one cycle and a cosine wave electric signal of one cycle in response to rotation of the rotator.

10. The rotation angle detection system according to claim 9, wherein
the magnetic flux detector is located on an extension of a radius of rotation of the pole pairs on the rotator or on a line intersecting with the extension of the radius of rotation of the pole pairs.
